(19) United States
(12) Patent Application Publication
(10) Pub. No.: US 2007/0238280 A1
(43) Pub. Date: Oct. 11, 2007

(54) Semiconductor device having contact plug and method for fabricating the same

(75) Inventors: Dae-Young Seo, Kyoungki-do (KR); Ki-Ro Hong, Kyoungki-do (KR); Do-Hyung Kim, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc.

(21) Appl. No.: 11/644,881

(22) Filed: Dec. 26, 2006

(30) Foreign Application Priority Data
Apr. 10, 2006 (KR) 10-2006-0032329
Dec. 4, 2006 (KR) 10-2006-0121416

(51) Int. Cl. H01L 21/44

(52) U.S. Cl. 438/597

(57) ABSTRACT

An improved method of fabricating a contact plug is described herein. The method includes forming a first insulation layer including a first contact hole over a substrate, forming protection layers on both sidewalls of the first contact hole, filling the first contact hole with a conductive material to form a first contact plug, forming a second insulation layer over the first insulation layer and the first contact plug, and forming a second contact hole exposing the first contact plug by etching a portion of the second insulation layer.

### BACKGROUND

The present invention relates to a method for fabricating a semiconductor device, and more particularly, to a method for forming a semiconductor device that can prevent bridges between landing plugs and storage node contact plugs adjacent to each other.

As the scale of integration has increased in dynamic random access memory (DRAM) device formation, landing plugs have been formed below bit line contacts and storage node contact plugs to form dense, integrated DRAM devices.

FIGS. 1A and 1B illustrate cross-sectional views showing a typical method for fabricating a semiconductor device. Referring to FIG. 1A, gate lines (not shown) are formed over a substrate 11. A first insulation layer is formed over the substrate structure. Predetermined portions of the first insulation layer are removed to form landing plug contact holes and a patterned first insulation layer 12. The landing plug contact holes are filled with a polysilicon layer to form landing plugs 13. A second insulation layer is formed over the landing plugs 13 and the patterned first insulation layer 12. The second insulation layer is selectively etched to expose a top surface of one of the landing plugs 13. A bit line contact 15 is formed over the exposed top surface. Subsequently, a bit line 16 is formed over the bit line contact 15. A third insulation layer is formed over the resultant substrate structure. The third insulation layer and the second insulation layer are selectively etched to form storage node contact holes 18 exposing top surfaces of the rest of the landing plugs 13. A wet cleaning process is performed to remove by-products of etching. Referring to FIG. 1B, the storage node contact holes 18 are filled with a polysilicon layer to form storage node contact plugs 19.

In the typical semiconductor device, the patterned first insulation layer 12 includes silicon dioxide (SiO₂) The patterned first insulation layer 12 functions as a landing plug isolation structure isolating the adjacent landing plugs 13. However, as the semiconductor device has become smaller, the bit line 16 may not be able to sufficiently cover the landing plug 13. Thus, the patterned first insulation layer 12 may be etched while forming the storage node contact holes 18 due to an alignment defect.

When the patterned first insulation layer 12 is etched due to the alignment defect, a portion of the patterned first insulation layer may be dissolved by a wet chemical used during the wet cleaning process for removing the by-products of etching, as denoted with reference letter ‘A’ in FIG. 1A. Since the insulation material between the landing plugs 13 is etched, undesired bridges ‘B’ may occur between the landing plug 13 and the storage node contact plug 19, which are not supposed to be in contact with each other.

### SUMMARY OF THE INVENTION

The present invention provides a semiconductor device and a method for fabricating the same, which can prevent bridges occurring between landing plugs and storage node contact plugs adjacent to each other.

In accordance with an aspect of the present invention, there is provided a method for fabricating a semiconductor device, including: forming a first insulation layer including a first contact hole over a substrate; forming protection layers on both sidewalls of the first contact hole; filling the first contact hole with a conductive material to form a first contact plug; forming a second insulation layer over the first insulation layer and the first contact plug; and forming a second contact hole exposing the first contact plug by etching a portion of the second insulation layer.

In accordance with another aspect of the present invention, there is provided a method for fabricating a semiconductor device, including: forming a first insulation layer including a landing plug contact hole over a substrate; forming protection layers on both sidewalls of the landing plug contact hole; filling the landing plug contact hole with a conductive material to form a landing plug poly; forming a second insulation layer over the first insulation layer and the landing plug poly; and forming a storage node contact hole exposing the landing plug poly by etching a portion of the second insulation layer.

In accordance with still another aspect of the present invention, there is provided a semiconductor device, including: a substrate; an insulation layer having a plurality of contact holes formed over the substrate; protection layers formed on sidewalls of the contact holes; a plurality of landing plugs filled in the contact holes; and a storage node contact plug formed over at least one of the landing plugs.

### BRIEF DESCRIPTION OF THE DRAWINGS

FIGS. 1A and 1B illustrate cross-sectional views to describe a typical method for fabricating a semiconductor device;

FIG. 2 illustrates a cross-sectional view of a semiconductor device consistent with an embodiment of this invention; and

FIGS. 3A to 3F illustrate cross-sectional views to describe a method for fabricating a semiconductor device consistent with an embodiment of this invention.

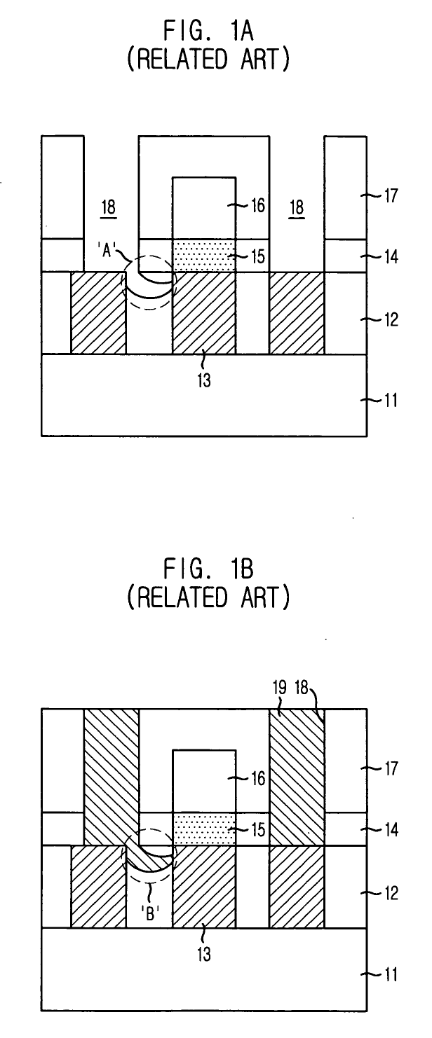

### DETAILED DESCRIPTION OF THE EMBODIMENTS

A semiconductor device having a contact plug and a method for fabricating the same in accordance with exemplary embodiments of the present invention will be described in detail with reference to the accompanying drawings. Furthermore, identical or like reference numerals throughout the exemplary embodiments of the present invention represent identical or like elements in different drawings.

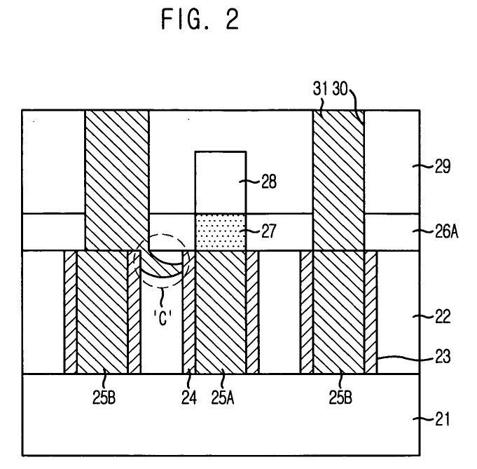

FIG. 2 illustrates a semiconductor device consistent with an embodiment of this invention. A patterned first insulation layer 22 including a plurality of contact holes 23 is formed over a substrate 21. Protection layers 24 are formed on both sidewalls of the contact holes 23. The protection layers 24 include a nitride-based layer, e.g., a silicon nitride layer. The contact holes 23 are filled with the landing plugs 25A and 25B, contacting the protection layers 24. The landing plugs 25A and 25B include polysilicon.

A second insulation pattern 26A is formed over the resultant substrate structure. A bit line contact 27 is formed in the second insulation pattern 26A, contacting the individual landing plug 25A. A bit line 28 is formed over the bit line contact 27.

A patterned third insulation layer 29 is formed over the resultant substrate structure. Storage node contact holes 30 are formed in the patterned third insulation layer 29, exposing top surfaces of the other landing plugs 25B. The storage node contact holes 30 are filled with storage node contact plugs 31. The storage node contact plugs 31 include polysilicon.

The patterned first insulation layer 22, the second insulation pattern 26A, and the patterned third insulation layer 29 include a silicon oxide layer. The protection layers 24 formed on the sidewalls of the contact holes 23 isolate the adjacent landing plugs 25A and 25B, functioning as a part of an isolation structure. The isolation structure formed between the adjacent landing plugs 25A and 25B is formed in a triple-layer structure, including a protection layer 24, the patterned first insulation layer 22, and another protection layer 24. Since the protection layers 24 include a silicon nitride layer and the patterned first insulation layer 22 includes a silicon oxide layer, the isolation structure in the triple layer structure includes a silicon nitride layer, a silicon oxide layer, and another silicon nitride layer.

In particular, the protection layers 24 prevent a bridge which may be generated between the landing plug 25A and the storage node contact plug 31 formed adjacent to each other. The landing plug 25A and the storage node contact plug 31 formed adjacent to each other are not supposed to be in contact with each other even when a portion of the first insulation layer 22 is dissolved during the wet etching process performed after forming the storage node contact holes 30. Thus, the protection layers 24 includes a material with a high wet etch selectivity, i.e., a silicon nitride layer, for the wet cleaning process of the patterned first insulation layer 22, the second insulation pattern 26A, and the patterned third insulation layer 29. Reference denotation ‘C’ denotes a portion of the storage node contact plug 31 filling a dissolved portion of the patterned first insulation layer 22.

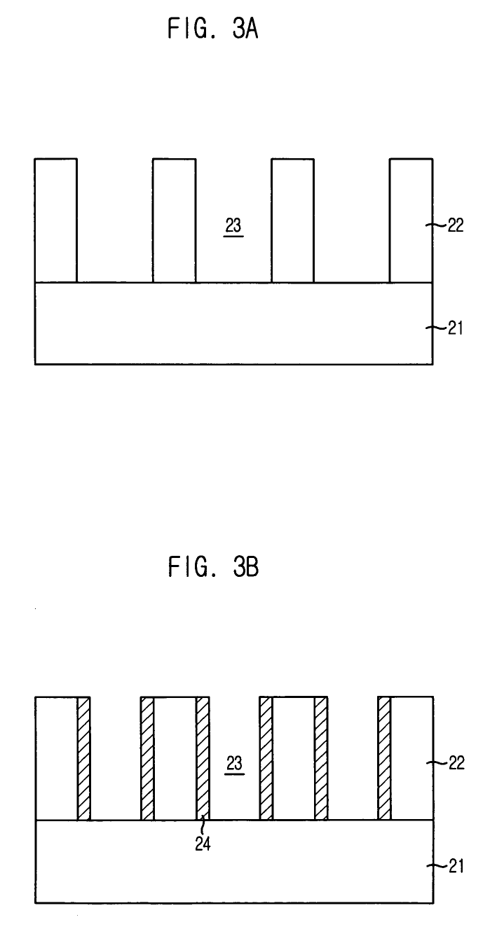

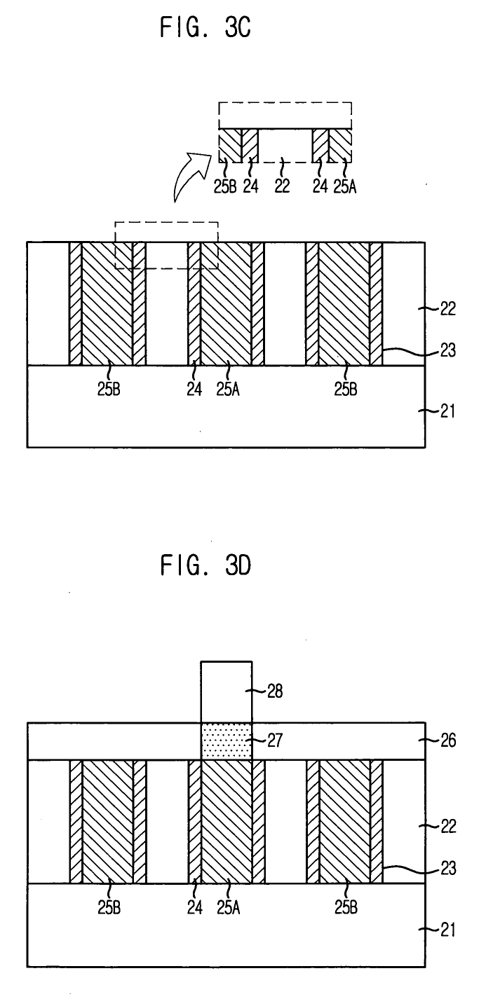

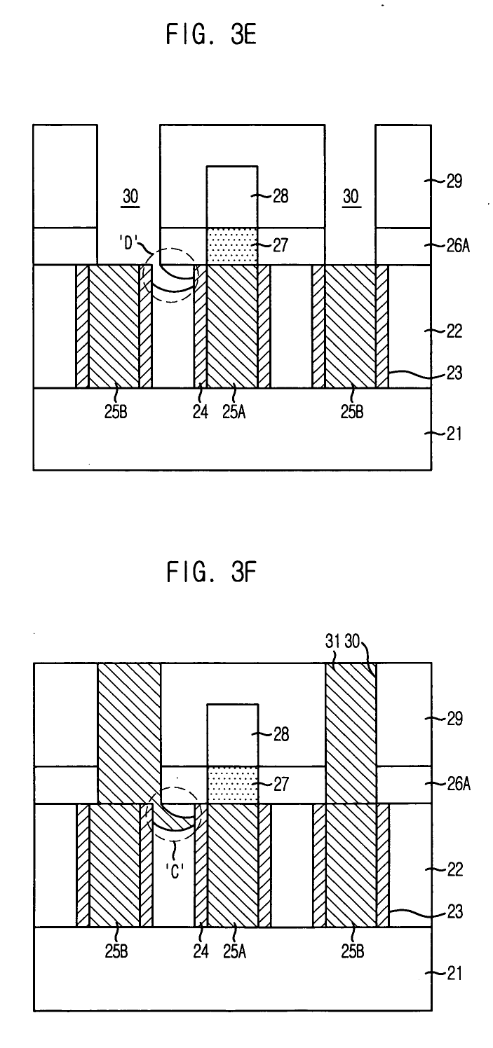

FIGS. 3A to 3F illustrate cross-sectional views to describe a method for fabricating a semiconductor device consistent with an embodiment of this invention.

Referring to FIG. 3A, predetermined processes are performed onto predetermined regions of a substrate 21. The predetermined processes refer to forming a transistor including an isolation structure, sources, drains, and gate electrodes. A plurality of gate lines (not shown) are formed over the substrate 21. A first insulation layer is formed over the substrate structure. A photolithography process is performed thereon to etch the first insulation layer to form a plurality of contact holes 23 in a patterned first insulation layer 22. The contact holes 23 are formed to connect subsequent landing plugs to portions of the substrate 21. Thus, the patterned first insulation layer 22 functions as a landing plug isolation layer. The patterned first insulation layer 22 includes an oxide-based layer such as a borophosphosilicate glass (BPSG) layer. The patterned first insulation layer 22 may include a silicon oxide layer.

Referring to FIG. 3B, protection layers 24 are formed on both sidewalls of the contact holes 23. The protection layers 24 have an etch rate different to that of the first insulation layer 22 and other subsequent insulation layers to be formed later. In more detail, an insulation layer is formed over the substrate structure. A dry etching process, i.e., an etch-back process, is performed onto the insulation layer in a manner that portions of the insulation layer remain on the sidewalls of the contact holes 23. The protection layers 24 are formed to prevent bridges from occurring between a subsequent storage node contact plug and an adjacent landing plug when a portion of the patterned first insulation layer 22 is dissolved-during a subsequent wet cleaning process. The protection layers 24 include a material insoluble to the wet chemical used during the wet cleaning process. The protection layers 24 may include a nitride-based layer. That is, the protection layers 24 may include a silicon nitride layer having a thickness ranging from approximately 100 Å to approximately 300 Å.

Referring to FIG. 3C, a conductive layer is formed over the resultant substrate structure, filling the contact holes 23. One of an etch-back process and a planarization process is performed thereon to form landing plugs 25A and 25B in the contact holes 23. The conductive layer may include polysilicon. The landing plug 25A refers to a landing plug which is to contact a bit line, and the landing plugs 25B refer to landing plugs which is to contact a storage node. In particular, an isolation structure formed between the adjacent landing plugs 25A and 25B is formed in a triple-layer structure, including a protection layer 24, the patterned first insulation layer 22, and another protection layer 24. Since the protection layers 24 include a silicon nitride layer and the patterned first insulation layer 22 includes a silicon oxide layer, the isolation structure in the triple layer structure includes a silicon nitride layer, a silicon oxide layer, and another silicon nitride layer.

Referring to FIG. 3D, a second insulation layer is formed over the resultant substrate structure. The second insulation layer includes an oxide-based layer such as a BPSG layer. The second insulation layer may include a silicon oxide layer. The second insulation layer is selectively etched to expose a bit line contact region. A conductive layer fills the bit line contact region to form a bit line contact 27 in a patterned second insulation layer 26. The bit line contact 27 is in contact with the landing plug 25A. A bit line 28 is formed over the bit line contact 27.

Referring to FIG. 3E, a third insulation layer is formed over the resultant substrate structure. The third insulation layer includes an oxide-based layer such as a BPSG layer. The third insulation layer may include a silicon oxide layer. A photolithography process is performed thereon to etch portions of the third insulation layer and the patterned second insulation layer 26, thereby forming storage node contact holes 30 and exposing top surfaces of the landing plugs 25B. Reference notation 29 denotes a patterned third insulation layer, and reference notation 26A denotes a second insulation pattern.

In more detail, a hard mask is formed over the third insulation layer. The third insulation layer and patterned second insulation layer 26 are selectively dry etched using the hard mask. A portion of the patterned first insulation layer 22 may be etched during the formation of the storage node contact holes 30 due to an alignment defect.

A wet cleaning process is performed onto the resultant substrate structure to remove by-products of etching. The wet etching process uses a wet chemical. The wet chemical may include a hydrogen fluoride (HF) solution or a buffered oxide etchant (BOE) solution. A portion of the patterned first insulation layer 22 may be dissolved, i.e., etched, during the wet cleaning process as denoted with reference letter ‘D’.

The wet chemical used in the wet cleaning process may etch the portion of the patterned first insulation layer 22, but does not etch the protection layers 24. In more detail, the protection layers 24 include a nitride-based layer which is indissoluble to the HF solution or the BOE solution, and thus, the protection layers 24 are not etched during the wet cleaning process. Consequently, sidewalls of the landing plugs 25A and 25B are protected from being exposed to the wet chemical by the protection layers 24.

Referring to FIG. 3F, the storage node contact holes 30 are filled with a conductive layer. An etch-back process or a planarization process is performed thereon to form storage node contact plugs 31. The conductive layer may include polysilicon. When forming the storage node contact plugs 31, a portion of the storage node contact plugs 31 may fill the dissolved portion of the patterned first insulation layer 22 as denoted with reference denotation ‘C’. However, the protection layers 24 formed on the sidewalls of landing plugs 25A and 25B prevent the storage node contact plugs 31 from bridging with the adjacent landing plug 25A.

Consistent with this embodiment, forming the protection layers, including a nitride-based layer which does not dissolve even when the patterned first insulation layer is dissolved by the wet chemical, on the sidewalls of the contact holes formed in the patterned first insulation layer isolating the adjacent landing plugs prevents generation of bridges between the storage node contact plugs and the adjacent landing plugs even when the patterned first insulation layer is dissolved by the wet chemical due to the misalignment defect. Consequently, device characteristics and yields may be improved.

The present application contains subject matter related to the Korean patent application Nos. KR 2006-0032329 and KR 2006-0121416, filed in the Korean Patent Office on Apr. 10, 2006 and Dec. 4, 2006, respectively, the entire contents of which are herein incorporated by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a first insulation layer including a first contact hole over a substrate;
forming protection layers on both sidewalls of the first contact hole;
filling the first contact hole with a conductive material to form a first contact plug;
forming a second insulation layer over the first insulation layer and the first contact plug; and
forming a second contact hole exposing the first contact plug by etching a portion of the second insulation layer.

2. The method of claim 1, wherein an etch rate of the material of the first and the second insulation layers differs from an etch rate of the material of the protection layer.

3. The method of claim 2, wherein the first and the second insulation layers comprise an oxide-based layer.

4. The method of claim 3, wherein the protection layers comprise a nitride-based layer.

5. The method of claim 4, wherein the protection layers comprise a silicon nitride layer.

6. The method of claim 1, wherein forming the second contact hole comprises dry etching the second insulation layer.

7. The method of claim 1, further comprising, after forming the second contact hole, performing a cleaning process using a wet chemical.

8. The method of claim 7, wherein the wet chemical is selected from the group consisting of a hydrogen fluoride (HF) solution and a buffered oxide etchant (BOE) solution.

9. The method of claim 1, further comprising, after forming the second contact hole, filling the second contact hole with a conductive material to form a second contact plug.

10. The method of claim 9, wherein the first contact plug comprises a landing plug and the second contact plug comprises a storage node contact plug.

11. A method for fabricating a semiconductor device, comprising:
forming a first insulation layer including a landing plug contact hole over a substrate;
forming protection layers on both sidewalls of the landing plug contact hole;
filling the landing plug contact hole with a conductive material to form a landing plug poly;
forming a second insulation layer over the first insulation layer and the landing plug poly; and
forming a storage node contact hole exposing the landing plug poly by etching a portion of the second insulation layer.

12. The method of claim 11, wherein the first and second insulation layers comprise an oxide-based layer and the protection layers comprise a nitride-based layer.

13. The method of claim 12, wherein the first and second insulation layers comprise a silicon oxide layer and the protection layers comprise a silicon nitride layer.

14. The method of claim 11, wherein forming the storage node contact hole comprises dry etching the second insulation layer.

15. The method of claim 11, further comprising, after forming the storage node contact hole, performing a cleaning process using a wet chemical.

16. The method of claim 15, wherein the wet chemical is selected from the group consisting of a HF solution and a BOE solution.

17. The method of claim 11, further comprising, after forming the storage node contact hole, filling the storage node contact hole with a conductive material to form a storage node contact plug.

18. A semiconductor device, comprising:
a substrate;
an insulation layer formed over the substrate having a plurality of contact holes;
protection layers formed on sidewalls of the contact holes;
a plurality of landing plugs in the contact holes; and
a storage node contact plug formed over at least one of the landing plugs.

19. The semiconductor device of claim 18, wherein the protection layers comprise a nitride-based layer and the insulation layer comprises an oxide-based layer.

20. The semiconductor device of claim 19, wherein the protection layers comprise a silicon nitride layer and the insulation layer comprises a silicon oxide layer.
